(19) United States
(12) Patent Application Publication
(10) Pub. No.: US 2002/0121663 A1
(43) Pub. Date: Sep. 5, 2002

(54) Semiconductor device and method

(75) Inventors: Misbahul Azam, Gilbert, AZ (US); Maureen Grimaldi, Chandler, AZ (US); Jeffrey Pearse, Chandler, AZ (US)

Correspondence Address: Robert D. Atkins, ON Semiconductor, Patent Administration Dept - MD A230, P.O. Box 62890, Phoenix, AZ, 85082-2890, US

(73) Assignee: Semiconductor Components Industries, LLC

(21) Appl. No.: 09/798,546

(22) Filed: Mar. 5, 2001

(51) Int. Cl. H01L 21/336; H01L 29/76; H01L 29/94; H01L 31/062; H01L 31/113; H01L 31/119

(52) U.S. Cl. 257/330; 438/259

(57) ABSTRACT

A semiconductor device (20) has a substrate (61) having a first surface (42) with a <110> crystal orientation and formed with a trench (50). A conduction path (72) is formed along a first surface (51) of the trench to provide a channel current (I_{D}) in response to a control signal (V_{GATE}).

### BACKGROUND OF THE INVENTION

The present invention relates in general to semiconductor devices and, more particularly, to power field effect transistors.

Power transistors typically are formed as vertical devices in which current flows vertically through the transistor from a top surface to a bottom surface of a semiconductor die. For example, many power metal-oxide-semiconductor field effect transistors are referred to as trench field effect transistors (FET) because the gate dielectric is formed along a vertical sidewall of a trench that has been etched in the top surface. The current is routed vertically through a conduction channel formed adjacent to the sidewall. Trench FETs occupy a smaller die area than planar FETs and therefore have a lower fabrication cost. In addition, the trench structure provides a short and well controlled conduction channel, thereby reducing the on resistance of the device. A typical power transistor is specified to supply at least one ampere of current and to have a breakdown voltage of at least twenty volts.

The processing step used with existing trench FETs to form the gate dielectric along a trench sidewall also disposes the dielectric material on the bottom surface of the trench. However, the dielectric layer at the bottom of the trench is thinner than the dielectric layer along the sidewalls. As a result, a higher electric field is produced on the bottom of the trench when the device is operated, and the existing trench FETS suffer from a high gate to drain capacitance and a low breakdown voltage.

Most manufacturers reduce the gate to drain capacitance by increasing the thickness of the dielectric layer on the sidewalls in order to increase the thickness at the bottom of the trench. However, this approach increases the conduction threshold of the transistor as well as its variability, which reduces device performance. Other schemes propose additional dielectric depositions and/or processing steps to increase the dielectric thickness only along the trench bottom, but these schemes produce complex structures which are difficult to control and costly to fabricate.

Hence, there is a need for a power trench field effect transistor which has a low conduction threshold, low gate to drain capacitance and a high breakdown voltage which maintains a low fabrication cost by avoiding the need for additional depositions or complex structures.

### BRIEF DESCRIPTION OF THE DRAWINGS

FIG. 1 shows an isometric view of a semiconductor wafer; and

FIG. 2 shows a cross-sectional view of a cell of a transistor.

### DETAILED DESCRIPTION OF THE DRAWINGS

In the figures, elements having the same reference numbers have similar functionality.

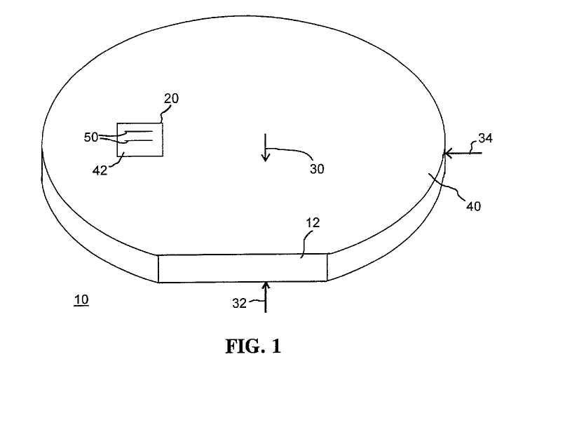

FIG. 1 is an isometric view of a semiconductor wafer 10 for fabricating a semiconductor device 20. Wafer 10 typically is formed as a monocrystalline silicon wafer which is cut and polished from a single crystal ingot (not shown) which is grown from a seed crystal that is aligned to produce a predetermined crystal orientation. The crystal orientation determines the lattice structure and periodicity of important crystal planes of a semiconductor material such as silicon. These crystal planes typically are represented by the Miller indices, which for a silicon crystal are designated as the <100> plane, the <110> plane, and the <111> plane. Each crystal plane has a unique physical structure and/or properties. For example, a <100> crystal orientation produces fewer surface states, i.e., a smaller surface charge, than other orientations. A small surface charge results in low device leakage and a well controlled conduction threshold. When heated in the presence of oxygen, a <100> surface has a low rate of silicon dioxide formation, while surfaces having a <110> orientation or a <111> orientation have higher oxidation rate. Moreover, a silicon dioxide layer on a <100> surface has a higher quality when used as a gate dielectric of a transistor than the quality of silicon dioxide grown on <110> or <111> surfaces. That is, a transistor's gate to source conduction threshold is more tightly controllable on a <100> surface, which increases the die per wafer yield and reduces the cost of the transistor. For at least these reasons, the <100> orientation typically is the preferred orientation for fabricating a gate dielectric of a metal-oxide-semiconductor field effect transistor (MOSFET).

Wafer 10 has a top surface 40 with a truncated circular shape including a wafer flat 12 that functions as a reference during die fabrication for aligning semiconductor device 20 to have a predetermined crystal orientation. Top surface 40 of wafer 10 has a <110> crystal orientation as viewed from a perspective normal to top surface 40 in the direction shown by an arrow 30. That is, an instrument looking in the direction of arrow 30 at top surface 40 sees a <110> crystal orientation. Similarly, other planes running through wafer 10 parallel to surface 40 have a <110> orientation due to the periodicity of the crystal lattice. Wafer flat 12 has a <100> crystal orientation as viewed from the perspective shown by an arrow 32, which is perpendicular to arrow 30. Similarly, planes running through wafer 10 parallel to wafer flat 12 have a <100> orientation. From a third perspective indicated by an arrow 34 perpendicular to arrows 30 and 32, wafer 10 has a <110> crystal orientation, and planes running through wafer 10 perpendicular to arrow 34 have a <110> orientation.

Semiconductor device 20 is configured as a trench power metal-oxide-semiconductor field effect transistor (MOSFET) 20 having a top surface 42 which is a portion of, and coplanar with, top surface 40 of wafer 10. A plurality of elongated trenches 50 are formed in surface 42 so that their sidewalls run parallel to wafer flat 12. The parallel alignment ensures that the sidewalls have a <100> crystal orientation, as viewed in the direction of arrow 32, while end surfaces have a <110> orientation and a bottom surface has a <110> orientation. MOSFET 20 is formed with trenches 50 as will now be described.

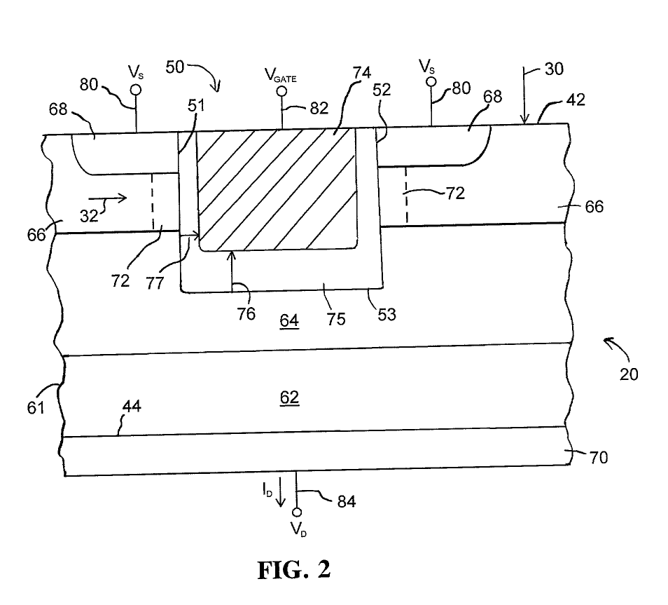

FIG. 2 is a cross sectional view of a cell of MOSFET 20 formed on a substrate 61 and showing a trench 50 as viewed in the direction of arrow 34. MOSFET 20 typically has an array of such cells which are essentially connected in parallel to provide a higher current capability. MOSFET 20 has a source electrode 80 for receiving a source voltage V_{S}, a gate electrode 82 receiving a control signal V_{GATE} and a drain electrode 84 for receiving a drain voltage V_{D}. MOSFET 20 is configured as a p-channel transistor having a surface 44 for mounting to a die attach flag 70 of a semiconductor package.

A drain region 62 is formed with a p-type conductivity and is heavily doped to provide a low on resistance and good ohmic contact to die attach flag 70 for coupling to drain electrode 84. In one embodiment, drain region 62 has a doping concentration of about 1.0*10¹⁹ atoms/centimeter³.

An epitaxial layer 64 is formed over drain region 62 to have a p-type conductivity but a lighter doping concentration. In one embodiment, epitaxial layer 64 is formed to a thickness of about five micrometers from drain region 62 to surface 42 and has an average doping concentration of about 6.0*10¹⁶ atoms/centimeter³.

A body region 66 is formed by doping epitaxial layer 64 to a typical depth of 1.0 micrometers from surface 42 with n-type dopants. Body region 66 has a light doping concentration which is conducive for inverting a portion of body region 66 to form a p-type conduction channel 72 of MOSFET 20. In one embodiment, body region 66 has a doping concentration of about 6.0*10¹⁷ atoms/centimeter³. A heavily doped n-type diffusion (not shown) is formed on surface 42 into body region 66 for applying a bias voltage.

A source region 68 is formed by diffusing p-type dopants from surface 42 into body region 66 to a depth of about 0.3 micrometers. Source region 68 is heavily doped to provide an ohmic contact to source electrode 80. In one embodiment, source region 68 has a doping concentration of about 1.0*10¹⁹ atoms/centimeter³.

Trench 50 is formed by etching wafer 10 to a depth of about 1.3 micrometers from surface 42 and a width of about 0.5 micrometers to form a bottom surface 53 and substantially vertical sidewalls 51 and 52. A portion of epitaxial layer 64 therefore lies adjacent to a lower portion of trench 50. Since MOSFET 20 is aligned on wafer 10 as previously described, sidewalls 51 and 52 have a <100> crystal orientation while bottom surface 53 has a <110> crystal orientation.

A dielectric layer 75 typically comprising silicon dioxide is formed along sidewalls 51 and 52 and bottom surface 53 by thermal oxidation. Due to a higher growth rate on a <110> surface than a <100> surface, dielectric layer 75 is thicker on bottom surface 53 than on sidewalls 51 and 52. In one embodiment, dielectric layer 75 is formed to a thickness W1 of about two hundred fifty angstroms along sidewalls 51-52 to achieve a specified source to gate conduction threshold voltage of about 1.0 volts. The thickness W2 of dielectric layer 75 along bottom surface 53 is at least three hundred angstroms.

A conductive material such as doped polysilicon is disposed in trench 50 adjacent to dielectric layer 75 to function as a gate 74. Gate 74 is electrically coupled to gate electrode 82 for receiving control signal V_{GATE}.

To appreciate the operation of MOSFET 20, assume that MOSFET 20 is turned on, with source electrode 80 biased to a source voltage V_{S}=0.0 volts, gate electrode 82 biased to control voltage V_{GATE}=−2.5 volts, and drain electrode 84 biased to a drain voltage V_{D}=−20.0 volts. Since the source to gate voltage (V_{S}−V_{GATE})=2.5 volts is greater than the conduction threshold of 1.0 volts, channel 72 is activated to provide a conduction path from source region 68 to epitaxial layer 64. A current I_{D} flows from source electrode 80 to surface 42 and is successively routed through source region 68, channel 72, epitaxial region 64 and drain region 62 to surface 44, die attach flag 70 and drain electrode 84.

Note that current I_{D} flows vertically through channel 72 in a <110> direction, i.e., parallel to arrow 30. Current carriers of MOSFET 20 are primarily holes, which have a higher mobility when flowing through the lattice in a <110> direction than their mobility when flowing in a <100> direction. As a result of the higher mobility, MOSFET 20 has a lower on resistance and a faster switching speed than previous devices whose current flows in a <100> direction.

To turn MOSFET 20 off, V_{S} and V_{GATE} are set to zero volts to deactivate the conduction channel. The drain to gate voltage (V_{D}−V_{GATE})=−20.0 volts produces an electric field 77 across dielectric layer 75 in a region adjacent to epitaxial layer 64 and sidewall 51 and across the PN junction formed between body region 66 and epitaxial layer 64. The thickness of dielectric layer 75 is selected so that this junction has a significantly lower breakdown voltage than the breakdown voltage of dielectric layer 75.

Similarly, an electric field 76 is produced across dielectric layer 75 in a region adjacent to bottom surface 53. Since bottom surface 53 has a <110> crystal orientation, dielectric layer 75 is thicker along bottom surface 53 than along sidewall 51. Therefore, electric field 76 is lower than electric field 77. Moreover, the capacitance per unit area is lower along bottom surface 53 than along sidewall 51, which reduces the overall gate to drain capacitance and increases the speed of MOSFET 20.

The thickness of dielectric layer 75 along sidewalls 51-52 is determined by the desired conduction threshold and breakdown voltage, and cannot readily be altered without affecting the transconductance or other conduction characteristics of MOSFET 20. Since dielectric layer 75 is thicker along bottom surface 53 and electric field 76 is lower than electric field 77, its breakdown voltage is higher along bottom surface 53 than the breakdown voltage along sidewall 51. Hence, the drain to gate breakdown voltage of MOSFET 20 is not limited by the breakdown voltage along bottom surface 53, as is the case with previous devices. Therefore, the thickness of dielectric layer 75 can be adjusted for optimized device performance and breakdown voltage without degrading other operating parameters or the reliability of the device.

In summary, the present invention provides a power transistor that a high cell density and has a low manufacturing cost. A substrate has a first surface with a <110> crystal orientation which is formed with a trench. A conduction path is formed along a first surface of the trench to provide a channel current in response to a control signal. The <110> crystal orientation produces a transistor with a lower gate to drain capacitance and a higher breakdown voltage than previous transistors. Because the channel current flows through the transistor vertically along a sidewall of the trench, a high cell density is achieved while avoiding the need for additional processing steps or complex structures.

What is claimed is:

1. A semiconductor device, comprising a substrate having a first surface with a <110> crystal orientation and formed with a trench, where a conduction path along a first surface of the trench is activated in response to a control signal for providing a channel current.

2. The semiconductor device of claim 1, wherein the first surface of the trench is substantially perpendicular to the first surface of the substrate.

3. The semiconductor device of claim 1, wherein the first surface of the trench has a <100> crystal orientation and a second surface of the trench has a <110> crystal orientation.

4. The semiconductor device of claim 3, further comprising a dielectric layer formed along the first and second surfaces of the trench.

5. The semiconductor device of claim 4, wherein the dielectric layer has a first thickness along the first surface of the trench and a second thickness greater than the first thickness along the second surface of the trench.

6. The semiconductor device of claim 5, further comprising a conductive material disposed within the trench for receiving the control signal.

7. The semiconductor device of claim 6, where the conduction path is formed in a body region of the substrate to have a first conductivity type.

8. The semiconductor device of claim 7, further comprising a first doped region formed at the first surface of the substrate to have a second conductivity type for routing the channel current to a first end of the conduction path.

9. The semiconductor device of claim 8, further comprising a second doped region formed in the substrate to have the second conductivity type for routing the channel current from a second end of the conduction path to a second surface of the substrate.

10. The semiconductor device of claim 9, wherein the second doped region is formed adjacent to the second surface of the trench.

11. A method of operating a semiconductor device, comprising the steps of:
providing a semiconductor substrate having a first surface with a <110> crystal orientation and defining a trench; and
activating a conduction path along a sidewall of the trench with a control signal to provide a channel current.

12. The method of claim 11, wherein the step of activating includes the step of routing the channel current in a <110> direction.

13. The method of claim 12, wherein the step of activating includes the step of generating a first electric field along the sidewall of the trench with the control signal.

14. The method of claim 13, wherein the step of generating includes the step of inducing the first electric field in a dielectric layer formed along the sidewall.

15. The method of claim 14, wherein the step of generating further includes the step of inducing a second electric field in the dielectric layer adjacent to a bottom surface of the trench, where the first electric field is greater than the second electric field.

16. The method of claim 15, further comprising the step of routing the channel current from the first surface of the semiconductor substrate to a first end of the conduction path.

17. The method of claim 16, further comprising the step of routing the channel current from a second end of the conduction path to a second surface of the semiconductor substrate.

18. A transistor, comprising:
a semiconductor substrate having a top surface with a <110> crystal orientation defined with a trench; and
a body region formed in the semiconductor substrate for inverting in response to a control signal to modify a current flowing adjacent to the trench.

19. The transistor of claim 18, wherein a sidewall of the trench has a <100> crystal orientation and the current flows through an inversion layer formed in the body region adjacent to the sidewall.

20. The transistor of claim 18, further comprising a semiconductor package for housing the semiconductor substrate and the body region.
